(19) United States
(12) Patent Application Publication
(10) Pub. No.: US 2009/0059496 A1
(43) Pub. Date: Mar. 5, 2009

(54) PORTABLE COMPUTER

(75) Inventor: Yi-Heng Lee, Taipei City (TW)

Correspondence Address: J C PATENTS, INC., 4 VENTURE, SUITE 250, IRVINE, CA, 92618, US

(73) Assignee: INVENTEC CORPORATION, Taipei City (TW)

(21) Appl. No.: 12/027,145

(22) Filed: Feb. 6, 2008

(30) Foreign Application Priority Data
Aug. 27, 2007 (TW) 96131691

(51) Int. Cl. H05K 7/00

(52) U.S. Cl. 361/681; 361/729; 361/683

(57) ABSTRACT

A portable computer is provided. The portable computer includes a host machine, a main display monitor, and at least one auxiliary display monitor. The host machine includes a processor adapted for dual display monitors. The processor provides data of a primary display mode and/or an auxiliary display mode according to an on/off state of at least one display monitor. The main display monitor is pivoted to the host machine for displaying the data of the primary display mode. The auxiliary display monitor is pivoted to the host machine for displaying data of the auxiliary display mode. The auxiliary display monitor is adapted to be turned on by pivotally turning an elevation angle relative to the host machine. Therefore, the elevation angle of the auxiliary display monitor can be flexibly adjusted, so as to allow the user to comfortably view the auxiliary display monitor.

### CROSS-REFERENCE TO RELATED APPLICATION

This application claims the priority benefit of Taiwan application serial no. 96131691, filed on Aug. 27, 2007. The entirety of the above-mentioned patent application is hereby incorporated by reference herein and made a part of this specification.

### BACKGROUND OF THE INVENTION

1. Field of the Invention

The present invention generally relates to a portable electronic device, and more particularly, to a portable computer having dual display monitors.

2. Description of Related Art

As electronic enterprises being rapidly developed, computers are now capable of calculating and accessing data at a higher speed, and storing mass data in a disk. In the meantime, differences between portable computers and desktop computers about hardware regulations are being gradually diminished. As such, besides consideration of requirements to the hardware regulations of the portable computers, the convenience associated with the portable computers are more drastically concerned. According to this consideration, in developing new generation portable computers, except for a powerful main system, a refined auxiliary system is further proposed, by which the user is capable of performing some routine jobs.

For example, a conventional portable computer may include a fixed auxiliary display monitor and an auxiliary control interface disposed at an upper cover of the main display monitor or at a peripheral of the host machine. In this way, the user is allowed to perform some routine jobs by the auxiliary display monitor and the auxiliary control interface without opening the main display monitor of the portable computer. Such routine jobs include playing multimedia files stored in the hard disk or in an optical storage media, sending/receiving emails or enquiring the battery capacity, or the like.

However, the auxiliary display monitor of the foregoing conventional portable computer is fixed on the upper cover, so that the angle of the auxiliary display monitor cannot be adjusted according to the operation conditions. As such, when the portable computer is flatly laid down, the auxiliary display monitor is affected and restricted by the viewing angle and reflection of ambient light, so as to make the user uncomfortable or inconvenient in viewing the auxiliary display monitor. In other words, the angle between the viewer's eyes and the flatly laid auxiliary display monitor makes the viewer uncomfortable. Further, because the display panel of the auxiliary display monitor is outwardly disposed on the upper cover, when combined with a metallic or plastic upper cover, it looks inconsistent in appearance. Therefore, further decoration is needed to fit the auxiliary display monitor when designing the upper cover.

### SUMMARY OF THE INVENTION

Accordingly, the present invention is directed to a portable computer having an auxiliary display which is adapted for being more comfortably viewed by a viewer.

The present invention provides a portable computer. The portable computer includes a host machine, a main display monitor, and at least one auxiliary display monitor. The host machine includes a processor adapted for dual display monitors. The processor provides data of a primary display mode and/or an auxiliary display mode according to an on/off status of at least one display monitor. The main display monitor is pivoted to the host machine for displaying the data of the primary display mode. The auxiliary display monitor is pivoted to the host machine for displaying the data of the auxiliary display mode. The auxiliary display monitor is adapted to be turned on by pivotally turning an elevation angle relative to the host machine.

According to an embodiment of the present invention, the main display monitor includes an accommodation opening for accommodating the auxiliary display monitor.

According to an embodiment of the present invention, the main display monitor includes a first slope configured at a side of the accommodation opening, and the auxiliary display monitor includes a second slope corresponding to the first slope, so that when the main display monitor is pivotally turned relative to the host machine, the auxiliary display monitor is synchronously pivotally turned together with the main display monitor. Further, when the auxiliary display monitor is independently opened, the first slope and the second slope are staggered and do not structurally interfere one to other.

According to an embodiment of the present invention, the portable computer further includes a driven structure. The driven structure is coupled between the main display monitor and the auxiliary display monitor, and is adapted for driving the auxiliary display monitor to synchronously pivotally turn with the main display monitor when the main display monitor pivotally turns relative to the host machine.

According to an embodiment of the present invention, the auxiliary display monitor includes a touch control panel.

According to an embodiment of the present invention, the auxiliary display monitor includes one of a liquid crystal display (LCD) and an organic light emitting diode display (OLED).

According to an embodiment of the present invention, the auxiliary display monitor is adapted for displaying a battery capacity, a power state, a signal intensity of a wireless network, and a data or multi-media images.

According to an embodiment of the present invention, the portable computer further includes a plurality of function keys disposed at the auxiliary display monitor.

According to an embodiment of the present invention, the function keys are disposed at one side of the auxiliary display monitor relatively apart from the host machine.

According to an embodiment of the present invention, the function keys include an auxiliary display monitor on/off key, an email sending/receiving key, a multi-media playing key, an audio volume adjusting key, a wireless network on/off key, a Bluetooth® on/off key, an office documents browsing key, and a direction key.

The present invention includes a main display monitor and an auxiliary display monitor, both of which are pivotally connected to the host machine, so that the user can flexibly adjust the elevation angle of the auxiliary display monitor for comfort viewing. Further, the auxiliary display monitor is adapted to conveniently open and close driven by the main display monitor. Furthermore, when the main display monitor and the auxiliary display monitor are closed, they appear consistent and thus look better than conventional.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view illustrating a portable computer in a state that a main display monitor and an auxiliary display monitor thereof are both closed, according to an embodiment of the present invention.

FIG. 2A is a schematic view illustrating the portable computer shown in FIG. 1 in a state that the auxiliary display monitor is open.

FIG. 2B is a schematic side view of the portable computer shown in FIG. 2A.

FIG. 2C is a schematic top view of the portable computer shown in FIG. 2A.

FIG. 3A is a schematic view illustrating the portable computer shown in FIG. 1 in a state that both of the main display monitor and the auxiliary display monitor are open.

FIG. 3B is a schematic side view of the portable computer shown in FIG. 3A.

FIG. 4 is a schematic view of the portable computer shown in FIG. 2A which further includes a driven structure.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

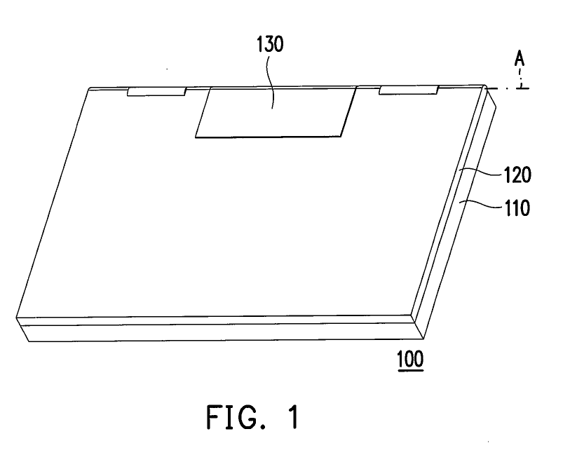

FIG. 1 is a schematic view illustrating a portable computer in a state that a main display monitor and an auxiliary display monitor thereof are both closed, according to an embodiment of the present invention. Referring to FIG. 1, a portable computer 100 is provided. The portable computer 100 includes a host machine 110, a main display monitor 120, and an auxiliary display monitor 130. The main display monitor 120 and the auxiliary display monitor 130 are both pivotally connected to the host machine 110, so that the main display monitor 120 and the auxiliary display monitor 130 are adapted to open by pivotally turning relative to the host machine 110 with respect to an axis A. The host machine 110 is adapted for processing electronic data, and displaying the processed result on the main display monitor 120 and/or the auxiliary display monitor 130. According to an aspect of the current embodiment, the main display monitor 120 for example is a high-grade display monitor, such as a high resolution LCD, and the auxiliary display monitor 130 for example is an elementary display monitor, such as a low resolution LCD or a low resolution OLED display.

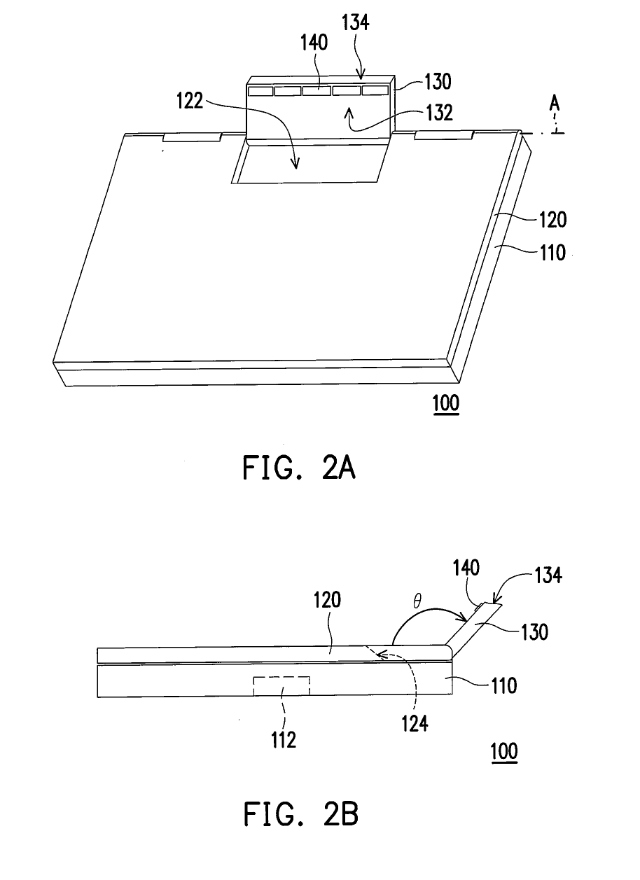

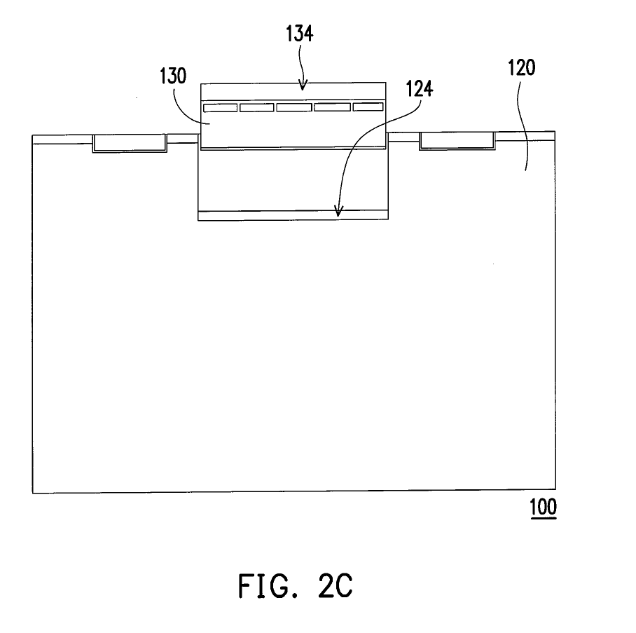

FIG. 2A is a schematic view illustrating the portable computer shown in FIG. 1 in a state that the auxiliary display monitor is open. FIG. 2B is a schematic side view of the portable computer shown in FIG. 2A. Referring to FIGS. 2A and 2B, the main display monitor 120 is closed and covers the host machine 110, while the auxiliary display monitor 130 is in a state of being open by pivotally turning an elevation angle 0 relative to the host machine 110. The main display monitor 120 includes an accommodation opening 122. The auxiliary display monitor 130 is adapted to be embedded in the accommodation opening 122 for accommodation as shown in FIG. 1.

The dual monitor display mode has an advantage that the user can perform jobs like document editing, summary brief, image processing via the main display monitor 120. However, in some certain circumstances, the user may like to handle some video/audio entertainment jobs and some simple routine jobs, such as displaying new emails, instant news, or calendar, or listening online music which are light loaded via the auxiliary display monitor 130. The present invention takes advantages of the new technologies of the new generation operation system, Window Vista™, and Slideshow™, by which an internal processor 112 of the host machine 110 supports the dual monitor display mode, so as to provide data of a main display mode and/or an auxiliary display mode, and display an image on the main display monitor 120 and/or the auxiliary display monitor 130. When the auxiliary display monitor 130 or the main display monitor 120 are open with respect to the host machine 110, the processor 112 of the host machine 110 is performed according to the on/off status of the auxiliary display monitor 130 or the main display monitor 120, for example powering on the host machine 110 or driving the host machine 110 from a standby mode to enter an operation mode.

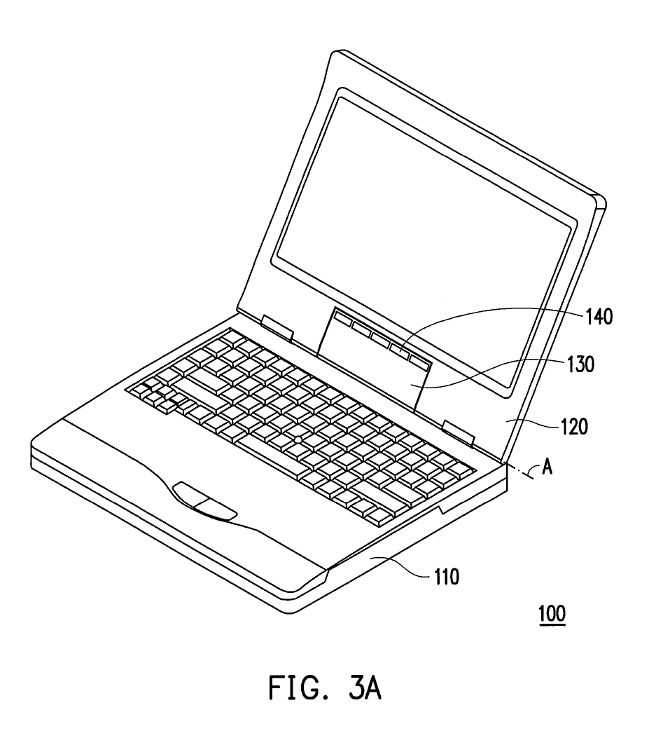

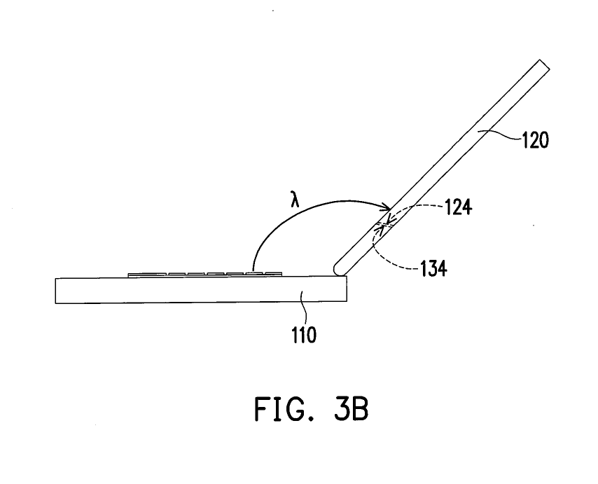

It should be noted that when the auxiliary display monitor 130 is open, the user can adjust the elevation angle 0 of the auxiliary display monitor 130 according to a viewing angle of the user's eyes viewing the auxiliary display monitor 130, so as to achieve a suitable angle for viewing and prevent unexpected reflection of ambient lights. Correspondingly, as shown in FIG. 1, when the auxiliary display monitor 130 is closed, a display area 132 (as shown in FIG. 3A) of the auxiliary display monitor 130 won't be exposed, and therefore the main display monitor 120 and the auxiliary display monitor 130 appear consistent and look well.

FIG. 2C is a schematic top view of the portable computer as shown in FIG. 2A. Referring to FIGS. 2B and 2C, the main display monitor 120 includes a first slope 124, and the auxiliary display monitor 130 includes a second slope 134 corresponding to the first slope 124. When the auxiliary display monitor 130 is independently opened, the first slope 124 of the main display monitor 120 would not be structurally interfered with the second slope 134 of the auxiliary display monitor 130. In such a way, the auxiliary display monitor 130 is adapted for pivotally turning a elevation angle 0 independent from the main display monitor 120.

FIG. 3A is a schematic view illustrating the portable computer shown in FIG. 1 in a state that both of the main display monitor and the auxiliary display monitor are open. FIG. 3B is a schematic side view of the portable computer as shown in FIG. 3A. Referring to FIG. 3A, the main display monitor 120 may be opened by pivotally turning relative to the host machine 110. Then referring to FIG. 3B, the main display monitor 120 is adapted to drive the auxiliary display monitor 130 to pivotally turn an equivalent angle λ together with the main display monitor 120 by contact and structural interference between the first slope 124 of the main display monitor 120 and the second slope 134 of the auxiliary display monitor 130.

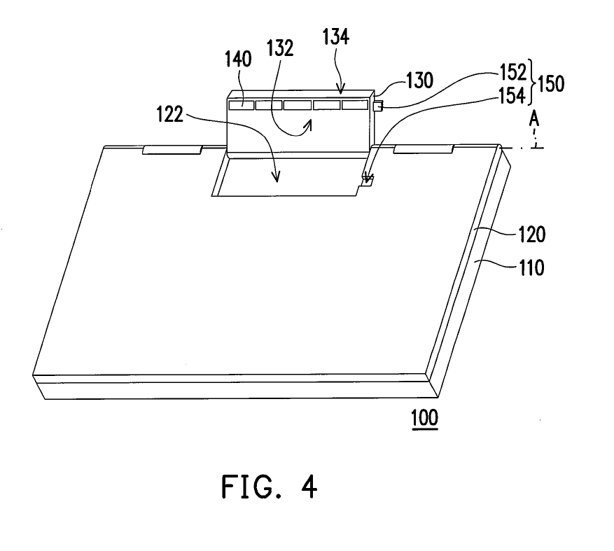

FIG. 4 is a schematic solid view of the portable computer as shown in FIG. 2A which further includes a driven structure. Referring to FIG. 4, the portable computer 100 further includes a driven structure 150, by which the auxiliary display monitor 130 can be driven to move together with the main display monitor 120. The driven structure 150 includes an engaging protrusion 152 and an engaging slot 154. The engaging protrusion 152 is disposed at one side of the auxiliary display monitor 130, and the engaging slot 154 is configured at a peripheral of the accommodation opening 122 corresponding to the engaging protrusion 152. The engaging protrusion 152 is adapted to be engaged with the engaging slot 154, by which the auxiliary display monitor 130 can be driven by the main display monitor 120 for pivotally turning synchronously together with the main display monitor 120. When the auxiliary display monitor 130 is to be independently opened, the engaging protrusion 152 can be released from the engaging slot 154, so that the auxiliary display monitor. 130 is not structurally interfered by the main display monitor 120, and thus allowing the auxiliary display monitor 130 for independently pivotally turning to open.

According to another embodiment of the present invention, the portable computer 100 may employ other driven structure at the main display monitor 120 and the auxiliary display monitor 130 to achieve a similar effect that the auxiliary display monitor 130 is driven to move together with the main display monitor 120. For example, a latch can be inserted between the main display monitor 120 and the auxiliary display monitor 130 for driving the auxiliary display monitor 130 to pivotally turn synchronously together with the main display monitor 120. When the auxiliary display monitor 130 is to be independently opened, the latch can be withdrawn from one of the main display monitor 120 and the auxiliary display monitor 130, so that the auxiliary display monitor 130 is not structurally interfered by the main display monitor 120, and thus allowing the auxiliary display monitor 130 for independently pivotally turning to open.

According to an aspect of the embodiment, in order to allow the user to perform system operation when the auxiliary display monitor 130 is independently open, the portable computer 100 further includes a plurality of function keys 140 as shown in FIG. 4. The function keys 140 can be disposed at the auxiliary display monitor 130, for example at one side of the auxiliary display monitor 130 apart from the host machine 110. By operating the function keys 140, the user are capable of turning on/off the auxiliary display monitor 130, sending/receiving emails, playing multi-media files, adjusting audio volumes, turning on/off a wireless network or a Bluetooth® network, browsing office documents or moving a cursor. In more details, when the user wants to browse the office documents or play the multi-media files with the auxiliary display monitor 130, the user can scroll images, page up/down the documents, switch songs by operating the function keys 140.

Besides the function keys 140 provided for the user to operate, the auxiliary display monitor 130 may further includes a touch control panel (not shown), by which the -user is allowed to perform the system operation in a way of touch controlling to display images on the auxiliary display monitor 130. When the main display monitor 120 and the auxiliary display monitor 130 are both open and turned on as shown in FIG. 3A, the auxiliary display monitor 130 can be responsible for displaying system information, such as battery capacity, power status, and signal intensity of the wireless network.

In summary, the present invention includes a main display monitor and an auxiliary display monitor, which are coaxially pivoted to the host machine, and has the following advantages:

1. the user can flexibly adjust the elevation angle of the auxiliary display monitor, so as to prevent reflection caused by ambient lights, and select a suitable angle for comfort viewing the auxiliary display monitor;

2. the driven structure is designed for the auxiliary display monitor and the main display monitor, and therefore the auxiliary display monitor can be driven by the main display monitor to open and close, thus saving operation to the auxiliary display monitor for opening/closing; and

3. when the main display monitor and the auxiliary display monitor are both closed, the display area of the auxiliary display monitor would not be outwardly exposed, thus the main display monitor and the auxiliary display monitor appear consistent and look well.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A portable computer, comprising:
a host machine, comprising a processor adapted for dual display monitors, wherein the processor provides data of a primary display mode and/or an auxiliary display mode according to an on/off state of at least one display monitor;
a main display monitor, pivoted to the host machine for displaying data of the primary display mode; and
an auxiliary display monitor, pivoted to the host machine for displaying data of the auxiliary display mode,
wherein the main display monitor and the auxiliary display monitor are coaxially pivoted to the host machine, and the auxiliary display monitor is adapted to be turned on by pivotally turning an elevation angle relative to the host machine.

2. The portable computer according to claim 1, wherein the main display monitor comprises an accommodation opening for accommodating the auxiliary display monitor.

3. The portable computer according to claim 2, wherein the main display monitor comprises a first slope configured at a side of the accommodation opening, and the auxiliary display monitor comprises a second slope corresponding to the first slope, so that when the main display monitor is pivotally turned relative to the host machine, the auxiliary display monitor is synchronously pivotally turned together with the main display monitor.

4. The portable computer according to claim 1 further comprising:
a driven structure, coupled between the main display monitor and the auxiliary display monitor, and adapted for driving the auxiliary display monitor to synchronously pivotally turn with the main display monitor when the main display monitor pivotally turns relative to the host machine.

5. The portable computer according to claim 1, wherein the auxiliary display monitor comprises a touch control panel.

6. The portable computer according to claim 1, wherein the auxiliary display monitor is a liquid crystal display (LCD) or an organic light emitting diode display (OLED).

7. The portable computer according to claim 1, wherein the auxiliary display monitor displays a battery capacity, a power state, a signal intensity of a wireless network, and a data or a multi-media image.

8. The portable computer according to claim 1 further comprising a plurality of function keys disposed at the auxiliary display monitor.

9. The portable computer according to claim 8, wherein the function keys are disposed at one side of the auxiliary display monitor relatively apart from the host machine.

10. The portable computer according to claim 8, wherein the function keys comprise at least one of an auxiliary display monitor on/off key, an email sending/receiving key, a multi-media playing key, an audio volume adjusting key, a wireless network on/off key, a Bluetooth® on/off key, an office documents browsing key, and a direction key.

11. The portable computer according to claim 4, wherein the auxiliary display monitor is driven by the driven structure to move together with the main display monitor when the main display monitor is opened.
